(19) United States
(12) Patent Application Publication
(10) Pub. No.: US 2026/0096043 A1
(43) Pub. Date: Apr. 2, 2026

(54) WATERPROOF MEMBER, WATERPROOF CASE, AND ELECTRONIC DEVICE

(71) Applicant: NITTO DENKO CORPORATION, Osaka (JP)

(72) Inventors: Hajime YAMAMOTO, Osaka (JP); Tamao FUKUSHIMA, Osaka (JP)

(73) Assignee: NITTO DENKO CORPORATION, Osaka (JP)

(21) Appl. No.: 19/138,363

(22) PCT Filed: Dec. 13, 2023
(86) PCT No.: PCT/JP2023/044746

§ 371 Date: Jun. 12, 2025

(30) Foreign Application Priority Data
Dec. 28, 2022 (JP) 2022-211979

(51) Int. Cl. H05K 5/06

(52) U.S. Cl. CPC H05K 5/069; H05K 5/068

(57) ABSTRACT

A waterproof member achieves waterproof properties and sound transmission properties. The waterproof member includes a waterproof membrane having a storage modulus E′ of 2.5×10⁶ Pa or more and 7.5×10⁶ Pa or less as measured by a dynamic mechanical analysis test in tensile mode in a frequency range of 100 to 500 Hz and satisfies at least one selected from (i) and (ii) below:
(i) an initial modulus measured by a tensile test is 30 MPa or more and 100 MPa or less; and
(ii) a puncture modulus measured according to a puncture strength test specified in JIS Z 1707: 2019 is 9.0 MPa or more and 40 MPa or less, the puncture modulus being calculated by dividing a maximum stress applied just before a needle penetrates the waterproof membrane by an amount of displacement of the waterproof membrane in a puncture direction at the maximum stress.

### TECHNICAL FIELD

The present invention relates to a waterproof member, a waterproof case including the waterproof member, and an electronic device including the waterproof member.

### BACKGROUND ART

Many electronic devices including a sound-relating component (acoustic component), which is, for example, a sound emitter, such as a speaker or a buzzer, or a sound receiver, such as a microphone, are carried and used outdoors. Such electronic devices are, for example, wearable devices, such as smartwatches, smartphones, mobile phones, and digital cameras. In recent years, it is required to impart a waterproof function to such electronic devices including an acoustic component while ensuring sound transmission properties. Waterproof smartwatches, waterproof smartphones, etc. are already widespread, and, in order to protect acoustic parts (acoustic components) of such devices, filters (waterproof sound transmission members) having a waterproof sound transmission function are used.

For example, a housing of a waterproof smartwatch including a microphone and a speaker is provided with openings at positions corresponding to the microphone and the speaker. These openings are covered with a waterproof sound-transmission membrane so as to ensure the sound transmission properties and the waterproof properties.

Using a microporous membrane including, for example, polytetrafluoroethylene (hereinafter referred to as “PTFE”) as a waterproof sound transmission member was proposed before (refer to Patent Literature 1, for example). In addition, using a non-porous membrane including an elastomer as a waterproof sound-transmission membrane was proposed recently (refer to Patent Literature 2, for example). Being a non-porous membrane, a waterproof sound-transmission membrane including an elastomer has higher waterproof properties than fine porous membranes including, for example, PTFE.

### CITATION LIST

### Patent Literature

Patent Literature 1: JP 2003-503991 A
Patent Literature 2: JP 2014-007738 A

### SUMMARY OF INVENTION

### Technical Problem

However, since the waterproof properties and the sound transmission properties are in a trade-off relationship, it has been difficult to achieve both at the same time.

Therefore, the present invention aims to provide a waterproof member suitable for achieving both the waterproof properties and the sound transmission properties at the same time, a waterproof case including such a waterproof member, and an electronic device including such a waterproof member.

### Solution to Problem

The present inventors made intensive studies and found that the above aim is achieved by adjusting each of the storage modulus and the initial modulus of a waterproof membrane including an elastomer within a certain range.

The present invention provides a waterproof membrane, wherein
the waterproof membrane has a storage modulus E′ of 2.5×10⁶ Pa or more and 7.5×10⁶ Pa or less as measured by a dynamic mechanical analysis test in tensile mode in a frequency range of 100 to 500 Hz and satisfies at least one selected from (i) and (ii) below:
(i) an initial modulus measured by a tensile test is 30 MPa or more and 100 MPa or less; and
(ii) a puncture modulus measured according to a puncture strength test specified in JIS Z 1707: 2019 is 9.0 MPa or more and 40 MPa or less, the puncture modulus being calculated by dividing a maximum stress applied just before a needle penetrates the waterproof membrane by an amount of displacement of the waterproof membrane in a puncture direction at the maximum stress.

In another aspect, the present invention provides a waterproof case including:
a case including a frame having an opening; and
the above waterproof member of the present invention disposed on the frame to cover the opening.

In still another aspect, the present invention provides an electronic device including:
a housing having an opening; and
the above waterproof member of the present invention disposed on the housing to cover the opening.

### Advantageous Effects of Invention

The present invention can provide a waterproof member suitable for achieving both the waterproof properties and the sound transmission properties at the same time, a waterproof case including such a waterproof member, and an electronic device including such a waterproof member.

### BRIEF DESCRIPTION OF DRAWINGS

FIG. 1A is a cross-sectional view schematically showing an example of a waterproof member of the present invention.

FIG. 1B is a perspective view schematically showing the waterproof member of FIG. 1A.

FIG. 2 is a cross-sectional view showing an example of a state where the waterproof member of FIG. 1A is installed on a housing of a device.

FIG. 3A is a cross-sectional view schematically showing another example of the waterproof member of the present invention.

FIG. 3B is a perspective view schematically showing the waterproof member of FIG. 3A.

FIG. 4 is a cross-sectional view showing an example of a state where the waterproof member of FIG. 3A is installed on a housing of a device.

FIG. 5A is a front view showing an example of a waterproof case of the present invention.

FIG. 5B is a back view of the waterproof case of FIG. 5A.

FIG. 6A is a cross-sectional view taken along line A-A of FIG. 5A.

FIG. 6B is a cross-sectional view taken along line B-B of FIG. 5A.

FIG. 7A is a top perspective view showing disposition of a waterproof case and an electronic device.

FIG. 7B is a bottom perspective view showing disposition of a waterproof case and an electronic device.

FIG. 8 is a front view showing an example of an electronic device of the present invention.

FIG. 9 is a graph showing elongation-stress relationships obtained by a tensile test for Samples 1 to 3.

FIG. 10 is a graph showing relationships between thickness and water entry pressure for Sample groups 1 to 3.

FIG. 11 is a schematic side view for illustrating a dynamic mechanical analysis test.

FIG. 12 is a schematic cross-sectional view for illustrating a puncture test.

FIG. 13 is a schematic diagram for illustrating the method for evaluating an insertion loss of a waterproof membrane.

### DESCRIPTION OF EMBODIMENTS

A waterproof member according to a first aspect of the present invention includes a waterproof membrane, wherein
the waterproof membrane has a storage modulus E′ of 2.5×10⁶ Pa or more and 7.5×10⁶ Pa or less as measured by a dynamic mechanical analysis test in tensile mode in a frequency range of 100 to 500 Hz and satisfies at least one selected from (i) and (ii) below:
(i) an initial modulus measured by a tensile test is 30 MPa or more and 100 MPa or less; and
(ii) a puncture modulus measured according to a puncture strength test specified in JIS Z 1707: 2019 is 9.0 MPa or more and 40 MPa or less, the puncture modulus being calculated by dividing a maximum stress applied just before a needle penetrates the waterproof membrane by an amount of displacement of the waterproof membrane in a puncture direction at the maximum stress.

According to a second aspect of the present invention, for example, in the waterproof member according to the first aspect, an insertion loss of the waterproof membrane for sound in a frequency range of 100 to 500 Hz is 10 dB or less.

According to a third aspect of the present invention, for example, in the waterproof member according to the first or second aspect, a water entry pressure measured for the waterproof membrane according to Method B (high water pressure method) of a water penetration test specified in JIS L 1092: 2009 is 200 kPa or more and 300 kPa or less.

According to a fourth aspect of the present invention, for example, in the waterproof member according to any one of the first to third aspects, a hardness measured for the waterproof membrane according to a type A durometer hardness test specified in JIS K 6253: 2012 is 40 or more and 60 or less.

According to a fifth aspect of the present invention, for example, in the waterproof member according to any one of the first to fourth aspects, the waterproof membrane includes an elastomer.

According to a sixth aspect of the present invention, for example, in the waterproof member according to the fifth aspect, the elastomer includes at least one selected from the group consisting of silicone rubber and urethane rubber.

According to a seventh aspect of the present invention, for example, in the waterproof member according to the fifth aspect, the elastomer is silicone rubber.

According to an eighth aspect of the present invention, for example, in the waterproof member according to any one of the first to seventh aspects, an areal density of the waterproof membrane is greater than 30 g/m².

According to a ninth aspect of the present invention, for example, in the waterproof member according to the fifth aspect, the elastomer is a mixture of a high hardness elastomer and a low hardness elastomer.

According to a tenth aspect of the present invention, for example, in the waterproof member according to any one of the first to ninth aspects, at least one principal surface of the waterproof membrane is subjected to an oil-repellent treatment.

According to an eleventh aspect of the present invention, for example, in the waterproof member according to any one of the first to tenth aspects, the waterproof membrane includes a colorant.

According to a twelfth aspect of the present invention, for example, the waterproof member according to any one of the first to eleventh aspects further includes a pressure-sensitive adhesive layer joined to the waterproof membrane.

A waterproof member according to a thirteenth aspect of the present invention includes:
a case including a frame having an opening; and
the waterproof member according to any one of the first to twelfth aspects disposed on the frame to cover the opening.

An electronic device according to a fourteenth aspect of the present invention includes:
a housing having an opening; and
the waterproof member according to any one of the first to twelfth aspects disposed on the housing to cover the opening.

Hereinafter, embodiments of the present invention will be described with reference to the drawings. The present invention is not limited to the embodiments described below.

### [Waterproof Member]

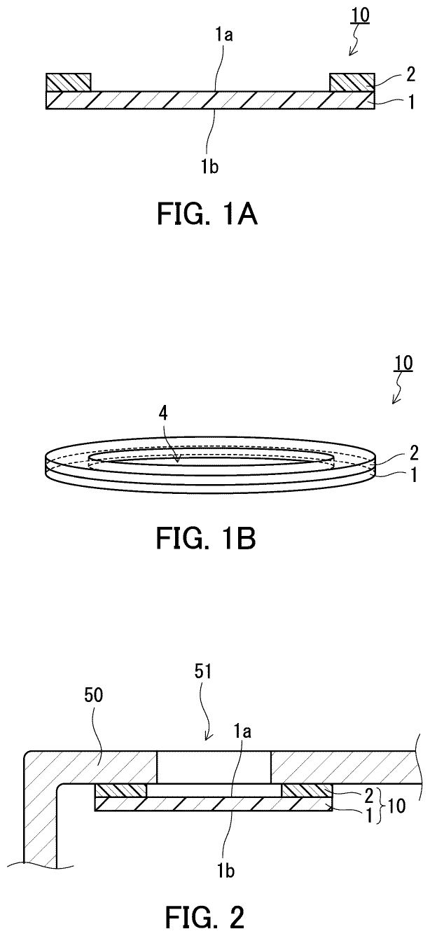

FIGS. 1A and 1B show an example of the waterproof member according to the present embodiment. A waterproof member 10 shown in FIGS. 1A and 1B includes a waterproof membrane 1. FIG. 2 is a cross-sectional view showing an example of a state where the waterproof member 10 is disposed to cover an opening 51 of a housing 50. As shown in FIG. 2, when used, the waterproof member 10 is disposed to cover the opening 51 of the housing 50.

The waterproof membrane 1 is a membrane adapted to permit passage of sound and prevent water ingress. The waterproof membrane 1 has a shape for covering the opening 51. The waterproof membrane 1 has a first principal surface 1a and a second principal surface 1b. When the waterproof membrane 1 is disposed on the housing 50, the first principal surface 1a faces the opening 51 and the second principal surface 1b faces the opposite side. Herein, to “face an opening” means to face the opening side. This is not limited to a case where two members face each other, and can also include a case where another member is present between the two members.

The waterproof membrane 1 has a storage modulus E′ of 2.5×10⁶ Pa or more and 7.5×10⁶ Pa or less as measured by a dynamic mechanical analysis test in tensile mode in a frequency range of 100 to 500 Hz and satisfies at least one selected from (i) and (ii) below:
(i) an initial modulus Eₜ measured by a tensile test is 30 MPa or more and 100 MPa or less; and
(ii) a puncture modulus Eₚ measured according to a puncture strength test specified in JIS Z 1707: 2019 is 9.0 MPa or more and 40 MPa or less, the puncture modulus Eₚ being calculated by dividing a maximum stress applied just before a needle penetrates the waterproof membrane 1 by an amount of displacement of the waterproof membrane 1 in a puncture direction at the maximum stress.

In the present embodiment, a measurement range in the dynamic mechanical analysis test is the frequency range of 0 to 20 kHz, which is a measurement range for sound transmission properties.

It is difficult for an acoustic component protective member including a waterproof membrane, as proposed in Patent Literature 2, formed of an elastomer to achieve both the waterproof properties and the sound transmission properties at the same time. The present inventors studied this problem, and found a new problem in that especially a waterproof membrane formed of an elastomer has a high insertion loss for sound in a low frequency region (the frequency range of 100 to 500 Hz). If an insertion loss for sound in the low frequency region can be reduced, it is possible to provide a waterproof member having enhanced sound transmission properties while ensuring waterproof properties. Therefore, the present inventors made intensive studies for a method for reducing an insertion loss of a waterproof membrane for sound in the low frequency region. That eventually directed the present inventors' attention to the elastic modulus of the membrane.

A vibration velocity of a membrane affects the sound transmission properties thereof. Specifically, as the vibration velocity of a membrane increases, the insertion loss decreases and the sound transmission properties of the membrane is enhanced. The vibration velocity is a value determined by differentiating an amount of displacement caused by vibration with respect to time. Therefore, the vibration velocity of the membrane increases by increasing the amount of displacement of the membrane. On the basis of these findings, the present inventors came up with an idea of adjusting the elastic modulus of a membrane so as to enhance the sound transmission properties thereof.

Furthermore, the present inventors gained a finding that because a membrane shows different properties at different frequencies, the storage modulus E′ which is a frequency-dependent parameter is more highly correlated with the sound transmission properties. On the basis of these findings, the present inventors came up with an idea of reducing the storage modulus E′ of a membrane so as to enhance the sound transmission properties of the membrane in the low frequency region. Meanwhile, according to studies by the present inventors, the initial modulus Eₜ and the puncture modulus Eₚ affect the waterproof properties of a membrane.

The waterproof membrane 1 having the storage modulus E′ adjusted in the above range and satisfying at least one selected from (i) and (ii) above can reduce the insertion loss in the low frequency region while ensuring the waterproof properties. Therefore, the waterproof member 10 is suitable for achieving both the waterproof properties and the sound transmission properties at the same time.

The lower limit of the storage modulus E′ of the waterproof membrane 1 may be 3.5×10⁶ Pa, 4.5×10⁶ Pa, 5.5×10⁶ Pa, or even 6.5×10⁶ Pa. The storage modulus E′ of the waterproof membrane 1 may be 6.7×10⁶ Pa or more and 7.4×10⁶ Pa or less.

The upper limit of the initial modulus Eₜ of the waterproof membrane 1 may be 90 MPa, 80 MPa, 70 MPa, 60 MPa, or even 55 MPa. The upper limit of the puncture modulus Eₚ of the waterproof membrane 1 may be 35 MPa, 30 MPa, or even 25 MPa. The waterproof membrane 1 may satisfy at least one of an initial modulus Eₜ of 31 MPa or more and 54 MPa or less and a puncture modulus Eₚ of 9.5 MPa or more and 23 MPa or less.

### (Method for Measuring Storage Modulus E′)

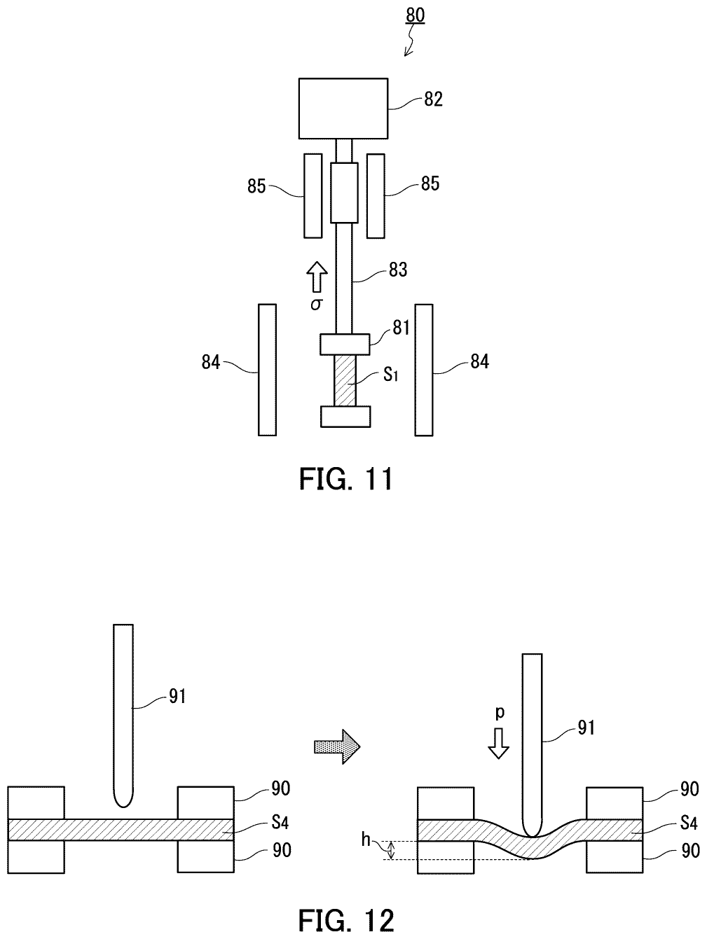

The storage modulus E′ can be measured by the following dynamic mechanical analysis test in tensile mode. Dynamic mechanical analysis (DMA) is one of the methods for determining a viscoelastic behavior of a sample piece. FIG. 11 is a schematic side view for illustrating tensile mode of a DMA apparatus. First, the waterproof membrane 1 is cut to a strip having a width of 10 mm and a length of 20 mm, which is employed as a sample piece S₁. Then, the sample piece S₁ is clamped to a measuring head 81 of a DMA apparatus 80 as shown in FIG. 11 such that a longitudinal direction of the sample piece S₁ is along the vertical direction. A stress (a frequency-dependent sinusoidal stress) σ in a tensile direction is applied to the clamped sample piece S₁ by a load generator 82 via a probe 83. The measurement frequency is in the range of 0 to 20 KHz. During the test, the temperature of the sample piece S₁ is adjusted at a temperature of −10 to 10° C. using a temperature adjuster 84. The stress σ is applied so that a strain amplitude of the sample piece S₁ is constant. In response to the stress σ, the sample piece S₁ gives a similar sinusoidal strain response with a viscosity-component-dependent phase delay. A displacement detector 85 detects an amplitude ratio σ/ε between the stress σ and a strain ε and a phase difference δ. The storage modulus E′ can be calculated using the amplitude ratio σ/ε and the phase difference δ. The thus-calculated storage modulus in the frequency range of 100 to 500 Hz is considered the storage modulus E′ of the waterproof membrane 1. In the present embodiment, the amplitude ratio σ/ε between the stress σ and the strain ε and the phase difference δ were detected for five sample pieces S₁, and an average of the storage moduli E′ calculated from these detected values is defined as the storage modulus E′ of the waterproof membrane 1.

### (Method for Measuring Initial Modulus Eₜ)

The initial modulus Eₜ, which is also called the Young's modulus, can be measured by the method described below. First, the waterproof membrane 1 is cut to a strip having a width of 5 mm and a length of 60 mm, which is employed as a sample piece S₂. The sample piece S₂ is pulled using a tensile tester in the longitudinal direction under conditions of a temperature at 25° C., a chuck-to-chuck distance of 40 mm, and a velocity of 300 mm/min to measure an elastic modulus at an elongation of 10%. The thus-measured elastic modulus is considered the initial modulus Eₜ of the waterproof membrane 1. In the present embodiment, the initial modulus Eₜ is measured for five sample pieces S₂, and an average of the measured values is defined as the initial modulus Eₜ of the waterproof membrane 1.

### (Method for Calculating Puncture Modulus Eₚ)

The puncture modulus Eₚ can be measured by the method described below according to the puncture strength test specified in JIS Z 1707: 2019. FIG. 12 is a schematic cross-sectional view for illustrating the puncture test. First, the waterproof membrane 1 is cut to a strip having a width of 10 mm and a length of 100 mm, which is employed as a sample piece S₄. Next, as shown in FIG. 12, the sample piece S₄ is fixed to a jig 90. The sample piece S₄ is punctured with a 1.0 mm-diameter needle 91 having a semicircular tip having a radius of 0.5 mm at a velocity of 10 mm/min. A maximum stress p (gf) applied just before the needle penetrates the sample piece S₄ and an amount of displacement h (mm) of the sample piece S₄ in a puncture direction at the maximum stress p are measured. The puncture modulus Eₚ can be calculated as a ratio (p/h) of the maximum stress p to the amount of displacement h. The thus-calculated puncture modulus Eₚ is considered the puncture modulus Eₚ of the waterproof membrane 1. In the present embodiment, the maximum stress p and the amount of displacement h are measured for five sample pieces S₄, and the average of the puncture moduli Eₚ calculated from the measured values is defined as the puncture modulus Eₚ of the waterproof membrane 1.

The insertion loss of the waterproof membrane 1, for example, for sound in the frequency range of 100 to 500 Hz is 10 dB or less. The waterproof membrane 1 having the above insertion loss in the above range has excellent sound transmission properties in a low frequency region. The lower limit of the above insertion loss of the waterproof membrane 1 is not limited to a particular one. The lower limit of the above insertion loss is, for example, 0.5 dB.

### (Method for Measuring Insertion Loss)

The method for measuring the insertion loss of the waterproof membrane 1 for sound in the frequency range of 100 to 500 Hz will be described in details in EXAMPLES.

For example, a water entry pressure measured for the waterproof membrane 1 according to Method B (high water pressure method) of a water penetration test specified in JIS L 1092: 2009 is 200 kPa or more and 300 kPa or less. The waterproof membrane 1 having the above water entry pressure in the above range has excellent waterproof properties. The lower limit of the above water entry pressure of the waterproof membrane 1 may be 210 kPa or more.

### (Method for Measuring Water Entry Pressure)

The water entry pressure of the waterproof membrane 1 can be measured by the method described below. First, the waterproof membrane 1 is prepared as a sample piece S₃. An example of a jig for measuring the water entry pressure is a 47 mm-diameter stainless steel disc provided with a 1 mm-diameter through hole (having a circular cross-section) at the center thereof. This disc is thick enough to resist deformation under a water pressure applied to measure the water entry pressure. The water entry pressure can be measured using this measurement jig in the following manner. The sample piece S₃ is fixed to one of the surfaces of the jig to cover an opening of the through hole of the measurement jig. The fixation of the sample piece S₃ is performed so that water will not leak from a fixed portion of the sample piece S₃ during the measurement of the water entry pressure. A double-sided pressure-sensitive adhesive tape having a water port punched in a central portion can be used for the fixation of the sample piece S₃, the water port having the same shape as that of the opening of the through hole of the measurement jig. The double-sided pressure-sensitive adhesive tape may be disposed between the measurement jig and the sample piece S₃ such that the circumference of the opening of the through hole of the measurement jig and the circumference of the water port are aligned. Next, the measurement jig to which the sample piece S₃ is fixed is set in a testing device such that the surface opposite to the surface on which the sample piece S₃ is fixed is a surface to which a water pressure is applied during the measurement. Then, the water entry pressure is measured according to Method B (high water pressure method) in JIS L 1092: 2009. It should be noted that the water entry pressure measured is a water pressure that causes water to come out from one spot of the surface of the sample piece S₃. The measured value can be employed as the water entry pressure of the waterproof membrane 1. In the present embodiment, the water entry pressure is measured for five sample pieces S₃, and the average of these measured values is defined as the water entry pressure of the waterproof membrane 1. As the testing device can be used a device having a specimen installation structure that allows the measurement jig to be set therein and having the same configuration as the water resistance test device exemplified in JIS L 1092: 2009.

The thickness of the waterproof membrane 1 is, for example, 5 μm or more and 40 μm or less. Because the thickness of the waterproof membrane 1 is in the above range, the waterproofness and the strength of the waterproof member 10 can be sufficiently ensured. The upper limit of the thickness of the waterproof membrane 1 may be 35 μm, or 30 μm. The lower limit of the thickness of the waterproof membrane 1 may be 10 μm, or 15 μm.

### (Method for Measuring Thickness)

The thickness of the waterproof membrane 1 can be determined by measuring the thickness at any five points on the waterproof membrane 1 and averaging the measured values.

For example, a hardness H_{A} measured for the waterproof membrane 1 according to a type A durometer hardness test specified in JIS K 6253: 2012 is 40 or more and 60 or less. The waterproof membrane 1 having a hardness H_{A} in the above range is likely to achieve a storage modulus E′ of 6.5×10⁶ Pa or more and 7.5×10⁶ Pa or less and an initial modulus Eₜ of 30 MPa or more and 55 MPa or less. The hardness H_{A} of the waterproof membrane 1 may be 45 or more and 60 or less, or 50 or more and 60 or less. Hereinafter, having a hardness H_{A} of 40 or more and 60 or less may be referred to as medium hardness.

### (Method for Measuring Hardness H_{A})

The hardness H_{A} can be measured using a type A durometer according to JIS K 6253: 2012.

The raw material of the waterproof membrane 1 is not limited to a particular one. The waterproof membrane 1 may include, for example, at least one selected from the group consisting of silicone rubber, polyurethane, and polytetrafluoroethylene. The waterproof membrane 1 may include at least one selected from the group consisting of silicone rubber and polytetrafluoroethylene.

The waterproof membrane 1 may be formed of a single raw material, or may be formed of a mixture of different raw materials.

The waterproof membrane 1 may include an elastomer. The waterproof membrane 1 may include the elastomer as its main component. Saying that “the waterproof membrane 1 includes the elastomer as its main component” means that the proportion (mass %) of the elastomer is larger than that of any other component included in the waterproof membrane 1. The waterproof membrane 1 may consist of the elastomer.

In the present embodiment, the waterproof membrane 1 is a non-porous membrane. Therefore, the waterproof member 10 is suitable particularly for enhancing waterproofness. In the present embodiment, the term “non-porous” means that a membrane has no or very few pores extending from one principal surface of the membrane to the other principal surface of the membrane. For example, a membrane can be classified as a non-porous membrane when having an air permeability, as expressed by Gurley number, of more than 10,000 seconds/100 mL. The Gurley number is a value obtained by measurement according to JIS P 8117: 2009.

The elastomer included in the waterproof membrane 1 is a rubber-like elastic body. The elastomer is preferably a rubber-like elastic body having rubber hardness, namely, the hardness H_{A}. The elastomer may be a thermosetting elastomer or a thermoplastic elastomer. The elastomer is not limited to a particular one. Examples of the elastomer include silicone rubber, urethane rubber, ethylene-propylene-diene rubber (EₚDM), acrylic rubber, and natural rubber. One of these or a combination of two or more of these can be used as the elastomer. Among these, silicone rubber or urethane rubber is used desirably. The elastomer may include at least one selected from the group consisting of silicone rubber and urethane rubber.

The elastomer included in the waterproof membrane 1 may be silicone rubber. By using silicone rubber as the elastomer included in the waterproof membrane 1, the sound transmission properties of the waterproof member 10 can be further enhanced.

An areal density of the waterproof membrane 1 may be greater than 30 g/m². The areal density, which is also called the surface density, of the waterproof membrane 1 is the mass of the waterproof membrane 1 per unit area.

For example, when the elastomer included in the waterproof membrane 1 is silicone rubber, it is possible to further enhance the waterproof properties of the waterproof member 10 and suppress a decrease of the sound transmission properties thereof by increasing the areal density beyond 30 g/m².

For example, when the elastomer included in the waterproof membrane 1 is silicone rubber, the upper limit of the areal density of the waterproof membrane 1 may be 65 g/m². The upper limit of the areal density of the waterproof membrane 1 may be 63 g/m².

The waterproof membrane 1 may be formed of a single elastomer. The waterproof membrane 1 may be formed of a mixture of different elastomers.

The waterproof membrane 1 may be formed of a mixture of a high hardness elastomer and a low hardness elastomer. That is, the elastomer included in the waterproof membrane 1 may be a mixture of a first elastomer having a relatively high hardness and a second elastomer having a lower hardness than that of the first elastomer. In the present embodiment, high hardness refers to, for example, a hardness H_{A} of more than 60 and 96 or less. Low hardness refers to, for example, a hardness H_{A} of 20 or more and less than 40. High hardness elastomers are commonly superior to low hardness elastomers in terms of waterproof properties. Low hardness elastomers are superior to high hardness elastomers in terms of sound transmission properties.

Studies by the present inventors have revealed that the waterproof membrane 1 formed of the mixture of the high hardness elastomer and the low hardness elastomer is superior to a waterproof membrane formed of a single elastomer in terms of sound transmission properties and waterproof properties. This is presumably because the high hardness elastomer and the low hardness elastomer are phase-separated (e.g., a sea-island structure) in the waterproof membrane 1 formed of the above mixture and therefore a portion formed of the high hardness elastomer exhibits excellent waterproof properties while a portion formed of the low hardness elastomer tends to vibrate to promote sound passing. Furthermore, it has been revealed that the above effect is particularly notable when the hardness H_{A} of the waterproof membrane 1 is 40 or more and 60 or less, i.e., when the above mixture is a medium hardness elastomer.

In the above mixture, a mass ratio between the high hardness elastomer and the low hardness elastomer is preferably in the range from 4:6 to 6:4. When the mass ratio between the high hardness elastomer and the low hardness elastomer is in this range, the waterproof membrane 1 is likely to achieve a good balance between the waterproof properties and the sound transmission properties.

At least one principal surface of the waterproof membrane 1 may be subjected to an oil-repellent treatment. In this case, the waterproof membrane 1 has higher waterproof properties.

Both principal surfaces of the waterproof membrane 1 may be subjected to the oil-repellent treatment.

The oil-repellent treatment can be performed by applying an oil repellent agent solution to at least one principal surface of the waterproof membrane 1 and drying the applied solution. The method for applying the oil repellent agent solution is not limited to a particular one, and, for example, spraying, spin coating, dipping, or roll coating can be employed. The oil repellent agent concentration in the oil repellent agent solution is preferably 0.1 to 10 weight %, more preferably 0.5 to 5.0 weight %.

The oil repellent agent is preferably, but not particularly limited to, a fluorine-based oil-repellent treatment agent. The fluorine-based oil repellent agent is preferably, for example, one or more selected from the group consisting of an acrylic polymer having a fluorine-containing side chain, a urethane polymer having a fluorine-containing side chain, and a silicone polymer having a fluorine-containing side chain. For example, a mixture of an oil repellent agent a including a polymer including a compound represented by the following chemical formula (a) as a monomer and a solvent can be used as the oil repellent agent.

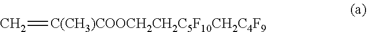

A solution mixture of 1,1,2,2-tetrafluoroethoxy-1-(2,2,2-trifluoro) ethane (hereinafter referred to as HFE-347pc-f) (AE-3000 manufactured by AGC Inc.) and meta-xylene hexafluoride (hereinafter referred to as MX-HF) can be used as the solvent. The mixing ratio of HFE-347pc-f to MX-HF is preferably 3:1 in volume.

A commercially-available product can be used as the above-described fluorine-based oil repellent agent. For example, UNIDYNE (registered trademark) series manufactured by DAIKIN INDUSTRIES, LTD., X-70-029C manufactured by Shin-Etsu Chemical Co., Ltd., or SFCOAT (registered trademark) series (e.g., SIF-200) manufactured by AGC Seimi Chemical Co., Ltd. can be used. Additionally, the fluorine-based oil repellent agent that is the silicone-based polymer is, for example, KP-801M manufactured by Shin-Etsu Chemical Co., Ltd.

The solvent of the oil repellent agent solution is preferably a fluorine-based solvent having a high affinity for a fluorine-containing side chain. A commercially-available product may be used as the fluorine-based solvent having a high affinity for a fluorine-containing side chain. Examples of the commercially-available product include FS Thinner manufactured by Shin-Etsu Chemical Co., Ltd. and Fluorinert manufactured by Sumitomo 3M Ltd. One of these may be used alone, or a mixture of two or more of these may be used.

The drying after the application of the oil repellent agent solution is not limited to particular drying, and may be natural drying (air drying) or heat drying. The drying after the application of the oil repellent agent solution is preferably heat drying at 40° C. to 120° C., more preferably heat drying at 50° C. to 110° C., in terms of high air permeability after attaching the oil.

The waterproof membrane 1 may be subjected to a coloring treatment. The waterproof membrane 1 that is transparent or white can be too conspicuous when the waterproof member 10 is disposed to cover an opening of a housing of a device. By coloring the waterproof membrane 1 according to the color of the housing where the waterproof member 10 is to be disposed, the waterproof member 10 that is not too conspicuous when disposed on the housing can be obtained. The waterproof membrane 1 may be colored, for example, black. Moreover, when the design of a housing is given importance, disposing the waterproof member 10 to cover an opening of the housing could damage the design. By coloring the waterproof membrane 1 to match the design of the housing, the design can be kept intact.

The waterproof membrane 1 can be colored, for example, by including a colorant in the raw material (e.g., the elastomer) included in the waterproof membrane 1. When attempting to obtain a design-oriented device, the colorant used desirably has a light absorptive capacity, for example, for light in at least part of the wavelength range from 380 nm to 500 nm. In other words, the waterproof membrane 1 is desirably colored black, gray, brown, green, yellow, or pink by this colorant. Examples of the method for coloring the waterproof membrane 1 include: a method in which coloring is performed by mixing a colorant such as a pigment or carbon black with a raw material including the raw material (e.g., the elastomer) yet to be formed into a sheet; and a method in which the raw material having been formed into a sheet (e.g., the elastomer in a sheet shape) is colored by a colorant using a dyeing or printing technique. When carbon black is used as the colorant, the strength of the waterproof membrane 1 can be enhanced, and the waterproofness thereof can also be enhanced.

The method for manufacturing the waterproof membrane 1 is not limited to a particular method, and can be selected as appropriate according to the intended use. Either of the following methods, for example, can be adopted: a method in which a raw material solution is extruded into a thin layer form onto a releasable substrate by a discharge means such as a die; and a method in which a raw material solution is cast onto a releasable substrate and is then formed into a thin film by an applicator, a wire bar, or a knife coater. Furthermore, the waterproof membrane 1 may be adjusted to a given thickness by cutting.

In one example, the waterproof membrane 1 formed of the elastomer being the mixture of the high hardness elastomer and the low hardness elastomer can be manufactured by the following method. First, a high hardness elastomer (e.g., a high hardness silicone rubber) G_{H} dissolved in ethyl acetate and a low hardness elastomer (e.g., a low hardness silicone rubber) G_{L} dissolved in ethyl acetate are mixed in a given mass ratio (e.g., G_{H}:G_{L}=40:60) and stirred to give a mixture. This mixture is used as a raw material solution and is shaped into a sheet. The waterproof membrane 1 formed of the elastomer being the mixture of the high hardness elastomer G_{H} and the low hardness elastomer G_{L} can be obtained in this manner.

As shown in FIGS. 1A and 1B, the waterproof member 10 may include a pressure-sensitive adhesive layer 2 joined to the waterproof membrane 1. In the present embodiment, the pressure-sensitive adhesive layer 2 is disposed on a periphery of the first principal surface 1a of the waterproof membrane 1. In FIG. 1B, a reference character 4 indicates a region through which sound passes when the waterproof member 10 is installed on a device, namely, a sound-passing region (sound transmission region).

The material of the pressure-sensitive adhesive layer 2 can be selected as appropriate so that the waterproof member 10 can be directly adhered and fixed to an acoustic component to which the waterproof member 10 is to be applied or so that the waterproof member 10 can be adhered and fixed to a housing in which such an acoustic component is to be enclosed. For example, a general-purpose double-faced tape having a substrate, a substrate-less double-faced tape (i.e., a tape consisting of a pressure-sensitive adhesive), or the like can be adopted as appropriate as the pressure-sensitive adhesive layer 2 in view of how firmly the double-faced tape adheres to the waterproof membrane 1 and a housing or a case. In the case where silicone rubber is adopted as the elastomer of the waterproof membrane 1, the pressure-sensitive adhesive layer 2 preferably has a surface consisting of a silicone pressure-sensitive adhesive, and the surface consisting of the silicone pressure-sensitive adhesive is preferably a surface in contact with the waterproof membrane 1. This is because silicone pressure-sensitive adhesives have extremely high bonding strength to silicone rubber, compared to other pressure-sensitive adhesives, such as acrylic pressure-sensitive adhesives.

In the example shown in FIGS. 1A and 1B, the pressure-sensitive adhesive layer 2 has a ring shape when viewed in a direction perpendicular to the principal surface of the waterproof membrane 1. The shape of the pressure-sensitive adhesive layer 2 is not limited to the shape in the example shown in FIGS. 1A and 1B.

In the example shown in FIGS. 1A and 1B, the waterproof member 10 is circular when viewed in the direction perpendicular to the principal surface of the waterproof membrane 1. The shape of the waterproof member 10 is not limited to the shape in the example shown in FIGS. 1A and 1B. The shape of the waterproof member 10 may be a circle (including a substantially circular shape), an ellipse (including a substantially elliptical shape), or a polygon, such as a rectangular or a square. A corner of the polygon may be rounded.

The thickness of the waterproof member 10 is, for example, 2000 μm or less. The thickness of the waterproof member 10 may be 1000 μm or less, 750 μm or less, 600 μm or less, 500 μm or less, 400 μm or less, or even 300 μm or less. The lower limit of the thickness of the waterproof member 10 is, for example, 50 μm.

### (Modification)

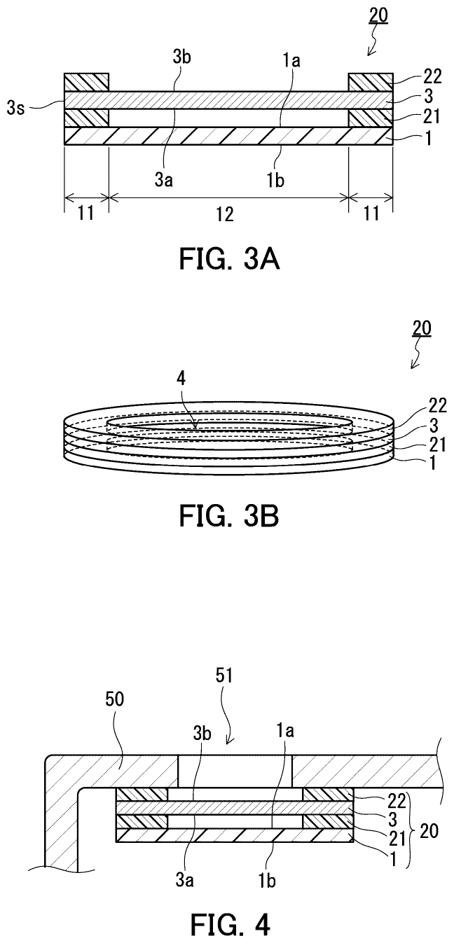

Next, FIGS. 3A and 3B show another example of the waterproof member according to the present embodiment. A waterproof member 20 shown in FIGS. 3A and 3B further includes a supporting layer 3 disposed apart from the waterproof membrane 1, the supporting layer 3 having air permeability in a thickness direction. Hereinafter, the elements of the waterproof member 20 that correspond to those of the waterproof member 10 are denoted by the same reference characters, and detailed descriptions of such components can be omitted.

FIG. 4 is a cross-sectional view showing an example of a state where the waterproof member 20 is disposed to cover the opening 51 of the housing 50. As shown in FIG. 4, when the waterproof member 20 is disposed to cover the opening 51, the supporting layer 3 is located between the waterproof membrane 1 and the housing 50.

The supporting layer 3 is provided to restrict deformation of the waterproof membrane 1 within a certain range. The supporting layer 3 has a first principal surface 3a and a second principal surface 3b. The first principal surface 3a and the second principal surface 3b face the first principal surface 1a of the waterproof membrane 1 and the opening 51, respectively, when the waterproof member 20 is disposed to cover the opening 51. As shown in FIG. 4, when the waterproof member 20 is disposed to cover the opening 51, the first principal surface 1a of the waterproof membrane 1 and the first principal surface 3a of the supporting layer 3 face each other across a space in contact with the first principal surface 1a and the first principal surface 3a.

As shown in FIGS. 3A and 3B, the waterproof member 20 includes a joining layer 21 joining the first principal surface 1a of the waterproof membrane 1 and the first principal surface 3a of the supporting layer 3. In the present embodiment, the joining layer 21 is disposed on the periphery of the first principal surface 1a of the waterproof membrane 1 and the periphery of the first principal surface 3a of the supporting layer 3.

As shown in FIG. 3A, the waterproof member 20 includes a joining region 11 where the waterproof membrane 1 and the supporting layer 3 are joined to each other and a non-joining region 12 surrounded by the joining region 11 when viewed in a direction perpendicular to the principal surface of the waterproof member 20. The joining region 11 includes a region corresponding to the peripheries of the waterproof membrane 1 and the supporting layer 3. The waterproof membrane 1 and the supporting layer 3 are joined by the joining layer 21.

As shown in FIG. 3A, the waterproof membrane 1 and the supporting layer 3 are separated apart from each other in the non-joining region 12. That is, the supporting layer 3 is disposed apart from the waterproof membrane 1 in the non-joining region 12.

The thickness of the supporting layer 3 in the non-joining region 12 is, for example, 500 μm or less. In this case, the waterproof member 20 can ensure favorable sound transmission properties even with the supporting layer 3. The thickness of the supporting layer 3 may be 300 μm or less, 250 μm or less, 200 μm or less, 150 μm or less, or even 100 μm or less. The lower limit of the thickness of the supporting layer 3 in the non-joining region 12 is, for example, 30 μm, and may be 50 μm. The supporting layer 3 may have the above thickness not only in the non-joining region 12. The entire supporting layer 3 may have the above thickness.

A separation distance between the waterproof membrane 1 and the supporting layer 3 in the non-joining region 12 is, for example, 150 μm or less. When the separation distance is 150 μm or less, the waterproof member 20 can ensure favorable sound transmission properties even with the supporting layer 3. The separation distance may be 125 μm or less, 100 μm or less, 75 μm or less, or even 50 μm or less. The lower limit of the separation distance is, for example, 5 μm, and may be 10 μm, 20 μm, or even 30 μm.

An air permeability resistance in an inplane direction of the supporting layer 3 may be 100,000 seconds/100 mL or more, 150,000 seconds/100 mL or more, 200,000 seconds/100 mL or more, 250,000 seconds/100 mL or more, 300,000 seconds/100 mL or more, or more than 300,000 seconds/100 mL. The upper limit of the air permeability resistance in the inplane direction of the supporting layer 3 is, for example, 1,000,000 seconds/100 mL or less. The air permeability resistance in the inplane direction of the supporting layer 3 can be evaluated as an air permeability resistance between a portion of the principal surface of the supporting layer 3 included in the waterproof member 20 and an outer peripheral side surface 3s of the supporting layer 3, the portion being located in the non-joining region 12. The term “air permeability resistance” herein means the time it takes for 100 mL of air to pass through the member in the inplane direction (thickness direction).

As shown in FIGS. 3A and 3B, the waterproof member 20 includes a pressure-sensitive adhesive layer 22 joined to the first principal surface 3a of the supporting layer 3. The pressure-sensitive adhesive layer 22 corresponds to the pressure-sensitive adhesive layer 2 in the waterproof member 10. In the present embodiment, the pressure-sensitive adhesive layer 22 is disposed on a periphery of the first principal surface 3a of the supporting layer 3. In FIG. 3B, the reference character 4 indicates a region through which sound passes when the waterproof member 20 is installed on a device, namely, a sound-passing region (sound transmission region).

In the example shown in FIGS. 3A and 3B, the waterproof member 20 and the non-joining region 12 are both circular when viewed in the direction perpendicular to the principal surface of the waterproof membrane 1. The shapes of the waterproof member 20 and the non-joining region 12 are not limited to the shapes in the example shown in FIGS. 3A and 3B. The shapes of the waterproof member 20 and the non-joining region 12 may each independently be a circle (including a substantially circular shape), an ellipse (including a substantially elliptical shape), or a polygon, such as a rectangular or a square. A corner of the polygon may be rounded.

The shape of the joining region 11 is not limited as long as the joining region 11 surrounds the non-joining region 12. The joining region 11 is typically a region including the periphery of the waterproof membrane 1 and/or the periphery of the supporting layer 3. In the example shown in FIGS. 3A and 3B, a region other than the joining region 11 where the waterproof membrane 1 and the supporting layer 3 are joined to each other is the non-joining region 12. In the example shown in FIGS. 3A and 3B, the waterproof membrane 1 is exposed to one surface of the waterproof member 20 (the surface that faces the outside when the waterproof member 20 is disposed on the housing 50) in the non-joining region 12. Additionally, the supporting layer 3 is exposed to the other surface of the waterproof member 20 (the surface that faces the opening 51 when the waterproof member 20 is disposed on the housing 50) in the non-joining region 12.

The shape of the waterproof membrane 1 and the shape of the supporting layer 3 may be the same or different when viewed in the direction perpendicular to the principal surface of the waterproof membrane 1. In the example shown in FIGS. 3A and 3B, the shape of the waterproof membrane 1 and the shape of the supporting layer 3 are the same, and are also the same as the shape of the waterproof member 20.

The thickness of the waterproof member 20 is, for example, 2000 μm or less. The thickness of the waterproof member 20 may be 1000 μm or less, 750 μm or less, 600 μm or less, 500 μm or less, 400 μm or less, or even 300 μm or less. The lower limit of the thickness of the waterproof member 20 is, for example, 50 μm.

Examples of the material of the supporting layer 3 include a metal, a resin, and a composite material thereof. The material of the supporting layer 3 is preferably a metal for excellent strength as the supporting layer 3. Examples of the metal include aluminum and stainless steel. Examples of the resin include various resins, such as polyolefins (polyethylene, polypropylene, etc.), polyesters (polyethylene terephthalate (PET), etc.), polyamides (various aliphatic polyamides, such as nylon, various aromatic polyamides, etc.), polycarbonates, and polyimides.

A specific example of the supporting layer 3 is a metal plate having one through hole or two or more through holes connecting the first principal surface 3a and the second principal surface 3b. The supporting layer 3 that is the metal plate is excellent particularly in strength. Moreover, when the supporting layer 3 is the metal plate, the rigidity and the handleability as the waterproof member 20 can be enhanced. The through hole extends, for example, in the thickness direction of the supporting layer 3. It is preferable to use the metal plate having two or more through holes because, in that case, the waterproof member 20 having both higher sound transmission properties and higher strength can be obtained. The through hole is required to be in at least the portion located in the non-joining region 12.

When the supporting layer 3 has two or more through holes, the openings of the through holes may be regularly arranged or irregularly positioned on the principal surface when viewed in a direction perpendicular to the principal surface of the metal plate.

The shape of the opening of the through hole is a circle (including a substantially circular shape), an ellipse (including a substantially elliptical shape), or a polygon, such as a square or a rectangular when viewed in the direction perpendicular to the principal surface of the metal plate. A corner of the polygon may be rounded. The shape of the opening of the through hole is not limited to the shape in the above example. In the case where there are two or more through holes, the shapes of the openings of the through holes may be the same or different.

The metal plate having two or more through holes is, for example, a perforated metal. The perforated metal is a metal plate provided with a through hole by punching (press punching).

An opening rate of the supporting layer 3 that is the above metal plate is, for example, 5 to 80%, and may be 15 to 40%, or even 15 to 30%. When the opening rate is in these ranges, the waterproof member 20 having both higher sound transmission properties and higher strength can be obtained. It should be noted that the opening rate of the supporting layer 3 that is the above metal plate is a ratio of the sum of the areas of the openings of all through holes in the principal surface of the supporting layer 3 to the area of the principal surface of the supporting layer 3.

Other examples of the supporting layer 3 include a mesh and a net formed of a metal, a resin, or a composite material thereof.

The air permeability of the supporting layer 3 in the thickness direction is commonly higher than the air permeability of the waterproof membrane 1 in the thickness direction. The air permeability of the supporting layer 3 in the thickness direction is, for example, 10 cm³/(cm²·sec) or more, and may be 100 cm³/(cm²·sec) or more, 300 cm³/(cm²·sec) or more, or even more than 500 cm³/(cm²·sec), as expressed in terms of an air permeability (Frazier air permeability) determined according to Method A for air permeability measurement (Frazier method) specified in JIS L 1096: 2010. The upper limit of the air permeability of the supporting layer 3 in the thickness direction is, for example, 1000 cm³/(cm²·sec) or less in terms of Frazier air permeability.

Even for the supporting layer 3 whose dimensions are smaller than those (about 200 mm×about 200 mm) of a specimen defined in the Frazier method, the Frazier air permeability can be evaluated using a measurement jig for limiting the area of a measurement region. One example of the measurement jig is a resin sheet provided with, at the center thereof, a through hole having a cross-sectional area corresponding to the area of a desirable measurement region. For example, a measurement jig provided with, at the center thereof, a through hole having a circular cross-section and having a diameter equal to or less than 1 mm can be used.

The strength of the supporting layer 3 is commonly higher than that of the waterproof membrane 1.

In the example shown in FIGS. 3A and 3B, the joining layer 21 has a ring shape when viewed in the direction perpendicular to the principal surface of the waterproof membrane 1. The shape of the joining layer 21 is not limited to the shape in the example shown in FIGS. 3A and 3B.

In the example shown in FIGS. 3A and 3B, the pressure-sensitive adhesive layer 22 has a ring shape when viewed in the direction perpendicular to the principal surface of the waterproof membrane 1. The pressure-sensitive adhesive layer 22 is not limited to the shape in the example shown in FIGS. 3A and 3B.

As shown in FIGS. 3A and 3B, the joining layer 21 and the pressure-sensitive adhesive layer 22 may each have a ring shape and may have the same area for joining.

The joining layer 21 is, for example, a pressure-sensitive adhesive layer or an adhesive layer. However, the configuration of the joining layer 21 is not limited as long as the joining region 11 and the non-joining region 22 can be formed. The joining layer 21 that is a pressure-sensitive adhesive layer or an adhesive layer can be formed, for example, by applying a known pressure-sensitive adhesive or adhesive to the periphery of the first principal surface 1a of the waterproof membrane 1. The joining layer 21 may be formed of a double-sided pressure-sensitive adhesive tape. That is, the waterproof membrane 1 and the supporting layer 3 may be joined to each other by a double-sided pressure-sensitive adhesive tape in the joining region 11. When the joining layer 21 is formed of a double-sided pressure-sensitive adhesive tape, the waterproof membrane 1 and the supporting layer 3 are more reliably joined to each other and thus the waterproof member 20 can have further enhanced waterproofness. Moreover, the separation distance between the waterproof membrane 1 and the supporting layer 3 in the non-joining region 12 is more easily controlled.

A known double-sided pressure-sensitive adhesive tape can be used as the double-sided pressure-sensitive adhesive tape forming the joining layer 21. A substrate of the double-sided pressure-sensitive adhesive tape is, for example, a resin film, a non-woven fabric, or a foam. The resin that can be included in the substrate is, for example, but not limited to, a polyester (such as PET), a polyolefin (such as polyethylene), or a polyimide. A variety of pressure-sensitive adhesives, such as acrylic pressure-sensitive adhesives and silicone pressure-sensitive adhesives, can be included in the pressure-sensitive adhesive layer of the double-sided pressure-sensitive adhesive tape. An acrylic pressure-sensitive adhesive is preferably included in the pressure-sensitive adhesive layer because, in that case, a joining force acting between the waterproof membrane 1 and the supporting layer 3 can be enhanced. The double-sided pressure-sensitive adhesive tape may be a thermal adhesive tape.

The thickness of the joining layer 21 is, for example, 150 μm or less. The thickness of the joining layer 21 may be 125 μm or less, 100 μm or less, 75 μm or less, or even 50 μm or less. The lower limit of the thickness of the joining layer 21 is, for example, but not limited to, 5 μm, and may be 10 μm, 20 μm, or even 30 μm.

The materials described for the pressure-sensitive adhesive layer 2 of the waterproof member 10 can be adopted as the material of the pressure-sensitive adhesive layer 22.

The material of the pressure-sensitive adhesive layer 22 may be the same as the material of the joining layer 21. For example, the same double-faced tape may be used as the pressure-sensitive adhesive layer 22 and the joining layer 21.

The method for installing the waterproof members 10 and 20 is not limited to a particular one as long as an acoustic component can be protected. For example, the waterproof member 10 may be directly adhered and fixed by the pressure-sensitive adhesive layer 2 or 22 to an acoustic component to which the waterproof member 10 or 20 is to be applied. Alternatively, the waterproof member 10 or 20 may be adhered and fixed by the pressure-sensitive adhesive layer 2 or 22 to a housing in which such an acoustic component is to be enclosed. In this case, for example, as shown in FIG. 2 and FIG. 4, the waterproof members 10 and 20 are fixed to the housing 50 by the pressure-sensitive adhesive layers 2 and 22 such that the waterproof membrane 1 covers the opening 51 provided in the housing 50. It should be noted that the opening 51 provided in the housing 50 is provided at a position corresponding to the acoustic component so as to allow sound to pass therethrough.

The method for manufacturing the waterproof members 10 and 20 is not limited to a particular method, and a method for manufacturing a conventional waterproof member can be used. For example, the waterproof member 10 can be manufactured by the following method. First, a sheet-shaped raw material for formation of the waterproof membrane 1 and a pressure-sensitive adhesive sheet (for example, a double-faced tape) for formation of the pressure-sensitive adhesive layer 2 are prepared. A hole corresponding to the sound-passing region 4 is formed beforehand in the pressure-sensitive adhesive sheet. This pressure-sensitive adhesive sheet and the sheet-shaped raw material are adhered together, and the resulting product is formed into a given shape by punching. The waterproof member 10 can be obtained in this manner. For example, the waterproof member 20 can be manufactured by the following method. First, a sheet-shaped raw material for formation of the waterproof membrane 1, a plate-shaped raw material for formation of the supporting layer 3, a first pressure-sensitive adhesive sheet (e.g., double-faced tape) for formation of the joining layer 21, and a second pressure-sensitive adhesive sheet (e.g., double-faced tape) for formation of the pressure-sensitive adhesive layer 22 are prepared. A hole corresponding to the sound-passing region 4 is formed beforehand in the first pressure-sensitive adhesive sheet and the second pressure-sensitive adhesive sheet. The sheet-shaped raw material, the first pressure-sensitive adhesive sheet, the plate-shaped raw material, and the second pressure-sensitive adhesive sheet are adhered together in this order, and the resulting product is formed into a given shape by punching. The waterproof member 20 can be obtained in this manner.

The present embodiment describes the waterproof member 10 in which the waterproof membrane 1 includes the pressure-sensitive adhesive layer 2; however, the waterproof member 10 does not necessarily include the pressure-sensitive adhesive layer 2. In the absence of the pressure-sensitive adhesive layer 2, the waterproof member 10 can be installed at a given position by holding and fixing the waterproof membrane 1 with an O-ring or the like or by fixing the waterproof membrane 1 by resin sealing. Additionally, although the present embodiment describes the waterproof member 20 in which the supporting layer 3 has the pressure-sensitive adhesive layer 22 thereon, the waterproof member 20 does not necessarily include the pressure-sensitive adhesive layer 22. In such a case, the waterproof member 20 can be installed at a given position by holding and fixing a laminate composed of the waterproof membrane 1, the joining layer 21, and the supporting layer 3 with an O-ring or the like or by fixing the laminate by resin sealing.

Moreover, although not shown, in the waterproof members 10 and 20, a net, a non-woven fabric, or the like may further be provided on the second principal surface 1b side of the waterproof membrane 1 for dust-proofing.

The applications of the waterproof members 10 and 20 are not limited. The waterproof members 10 and 20 can be used in applications where both sound transmission and waterproofness are essential: for example, a waterproof sound transmission structure, an article having a waterproof sound transmission structure, and the like. The waterproof members 10 and 20 are typically included in electronic devices having an audio function. The waterproof member 10 may be included in tiny products, such as micro electro mechanical systems (MEMS). The waterproof members 10 and 20 may be applied to a circuit board where an acoustic MEMS component is mounted.

### [Waterproof Case]

The waterproof members 10 and 20 can also be applied to a waterproof case in which an electronic device including an acoustic component is to be enclosed. Hereinafter, an embodiment of a waterproof case of the present invention will be described.

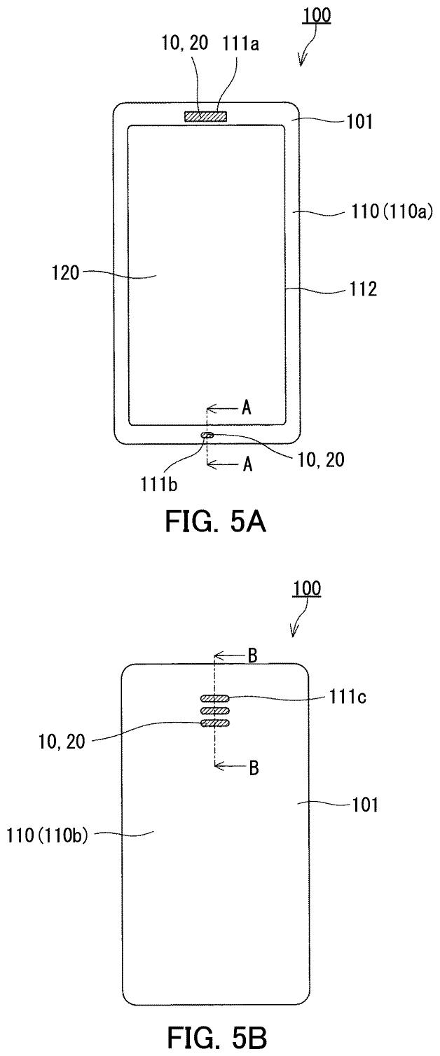

As shown in FIGS. 5A and 5B, the waterproof case 100 includes the above waterproof member 10 or 20 and a case 101. The waterproof membrane 1 included in the waterproof member 10 or 20 has a storage modulus E′ of 2.5×10⁶ Pa or more and 7.5×10⁶ Pa or less as measured by the dynamic mechanical analysis test in tensile mode in the frequency range of 100 to 500 Hz and satisfies at least one selected from (i) and (ii) below:
(i) the initial modulus Eₜ measured by the tensile test is 30 MPa or more and 100 MPa or less; and
(ii) the puncture modulus Eₚ measured according to the puncture strength test specified in JIS Z 1707: 2019 is 9.0 MPa or more and 40 MPa or less, the puncture modulus Eₚ being calculated by dividing a maximum stress applied just before a needle penetrates the waterproof membrane 1 by the amount of displacement of the waterproof membrane 1 in the puncture direction at the maximum stress.

The case 101 includes a frame 110 and a transparent elastic film 120. The frame 110 includes an upper frame 110a and a lower frame 110b. The upper frame 110a has a thin-plate-shaped structure having a rectangular outline and having a rectangular opening arranged at the center. The upper frame 110a includes a sound transmission opening 111a, a sound transmission opening 111b, and an operation opening 112. The lower frame 110b has a shape of a bottomed box having an open top and includes a sound transmission opening 111c in the bottom surface. The transparent elastic film 120 is disposed on and applied to the upper frame 110a to cover the operation opening 112. The transparent elastic film 120 is, for example, a silicone rubber film, a urethane rubber film, or a glass.

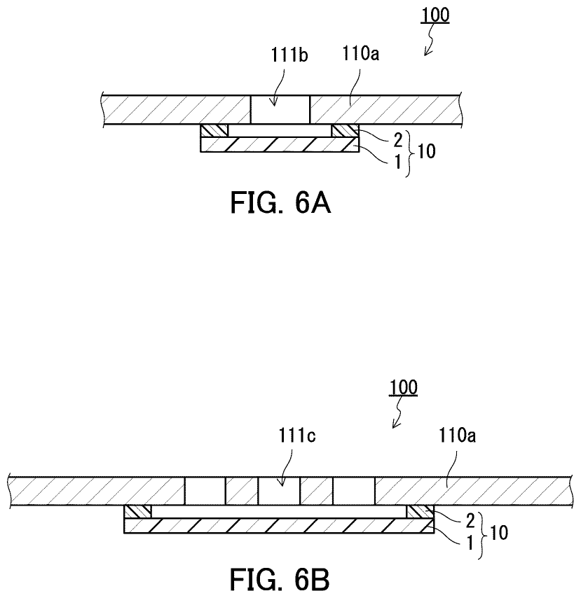

FIG. 6A is a cross-sectional view taken along line A-A of FIG. 5A. FIG. 6B is a cross-sectional view taken along line B-B of FIG. 5A. FIGS. 6A and 6B show a case where the waterproof case 100 includes the waterproof member 10. As shown in FIG. 6A, the waterproof member 10 is disposed on and joined to the upper frame 110a via the pressure-sensitive adhesive layer 2 to cover the sound transmission opening 111b. Although not shown, the waterproof member 10 is disposed on and joined to the upper frame 110a via the pressure-sensitive adhesive layer 2 to cover the sound transmission opening 111a. As shown in FIG. 6B, the waterproof member 10 is joined to the lower frame 110b via the pressure-sensitive adhesive layer 2 to cover the sound transmission opening 111c.

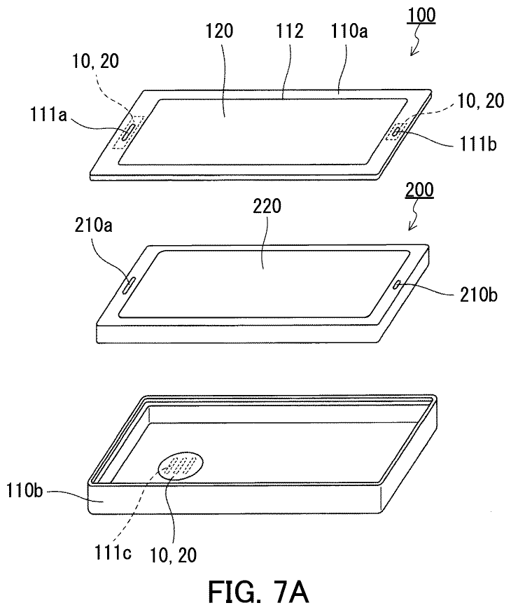

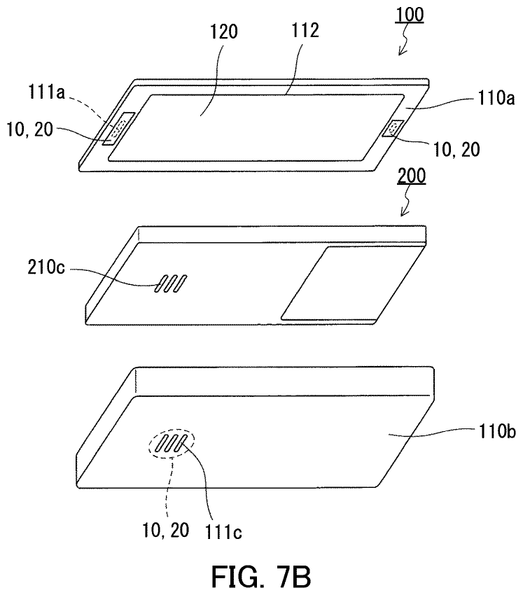

By assembling the upper frame 110a and the lower frame 110b such that the upper frame 110a covers the opening of the lower frame 110b, the inside of the case 101 is made waterproof. Therefore, as shown in FIGS. 7A and 7B, an electronic device 200, such as a smartphone, is disposed between the upper frame 110a and the lower frame 110b to enclose the electronic device 200 inside the case 101, so that the electronic device 200 can be used in an environment where waterproofness is required.

In a state where the electronic device 200 is enclosed inside the case 101, the sound transmission opening 111a is located in a region corresponding to a speaker sound transmission port 210a of the electronic device 200. In a state where the electronic device 200 is enclosed inside the case 101, the sound transmission opening 111b is located in a region corresponding to a microphone sound transmission port 210b of the electronic device 200. In a state where the electronic device 200 is enclosed inside the case 101, the sound transmission opening 111c is located in a region corresponding to a speaker sound transmission port 210c of the electronic device 200. Therefore, in a state where the electronic device 200 is enclosed inside the case 101, sound transmits between a speaker or microphone of the electronic device 200 and the outside of the case 101. Therefore, a user can use the speaker or microphone of the electronic device 200 in a state where the electronic device 200 is enclosed inside the case 101.

In a state where the electronic device 200 is enclosed inside the case 101, the transparent elastic film 120 is in contact with the electronic device 200 to cover a touch panel display 220 of the electronic device 200. A user can operate the display 220 through the transparent elastic film 120 and can view the display 220 through the elastic film 120. As described above, a user can operate the electronic device 200 in a state where the electronic device 200 is enclosed inside the case 101.

### [Electronic Device]

The waterproof member 10 can also be applied to an electronic device having an audio function. Hereinafter, an embodiment of an electronic device of the present invention will be described.

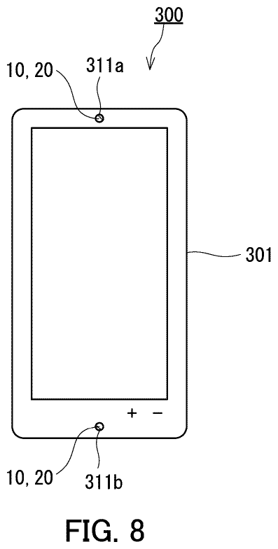

FIG. 8 shows an example of an electronic device including the waterproof member 10 or 20. The electronic device shown in FIG. 8 is a smartphone 300. The smartphone 300 includes the above waterproof member 10 or 20 and a housing 301. The waterproof membrane 1 included in the waterproof member 10 or 20 has a storage modulus E′ of 2.5×10⁶ Pa or more and 7.5×10⁶ Pa or less as measured by the dynamic mechanical analysis test in tensile mode in the frequency range of 100 to 500 Hz and satisfies at least one selected from (i) and (ii) below:
(i) the initial modulus Eₜ measured by the tensile test is 30 MPa or more and 100 MPa or less; and
(ii) the puncture modulus Eₚ measured according to the puncture strength test specified in JIS Z 1707: 2019 is 9.0 MPa or more and 40 MPa or less, the puncture modulus Eₚ being calculated by dividing a maximum stress applied just before a needle penetrates the waterproof membrane 1 by the amount of displacement of the waterproof membrane 1 in the puncture direction at the maximum stress.

A sound transducer that performs conversion between an electrical signal and sound is disposed inside the housing 301 of the smartphone 300. The sound transducer (sound transducer) is, for example, a speaker or a microphone. The sound transducer may be a microphone. Openings 311a and 311b that are external sound transmission ports are provided to the housing 301.

In the smartphone 300, a first waterproof member 10 or 20 is disposed on the housing 301 to cover the opening 311a. Moreover, a second waterproof member 10 or 20 is disposed on the housing 301 to cover the opening 311b. The second principal surface 1b of the waterproof membrane 1 of each of the waterproof members 10 and/or 20 faces the outside with the opening 311a or 311b in between.

Additionally, the first and second waterproof members 10 or 20 are each fixed to the sound transducer enclosed inside the housing 301 (not illustrated). The other principal surface of each of the waterproof members 10 or 20 is in contact with the sound transducer.

The electronic device including the waterproof member 10 or 20 is not limited to the smartphone 300. Examples of the electronic device include: wearable devices such as smartwatches and wristbands; various cameras such as action cameras and security cameras; communication devices such as mobile phones and smartphones; virtual reality (VR) devices; augmented reality (AR) devices; and sensor devices. The electronic device may be, for example, a tiny product, such as a MEMS.

### EXAMPLES

Hereinafter, the present invention will be described more specifically by way of examples. The present invention is not limited to the examples given below.

First, evaluation methods for waterproof membranes produced in the examples will be described.

The hardness H_{A}, the thickness, the initial modulus Eₜ, the puncture modulus Eₚ, the water entry pressure, and the storage modulus E′ of each waterproof membrane were evaluated by the above methods. GS-615 manufactured by TECLOCK Co., Ltd. was used as the type A durometer. Autograph AGS-X manufactured by Shimadzu Corporation was used as the tensile tester. DM6100 manufactured by Hitachi High-Tech Science Corporation was used as the DMA apparatus.

### (Method for Measuring Insertion Loss)

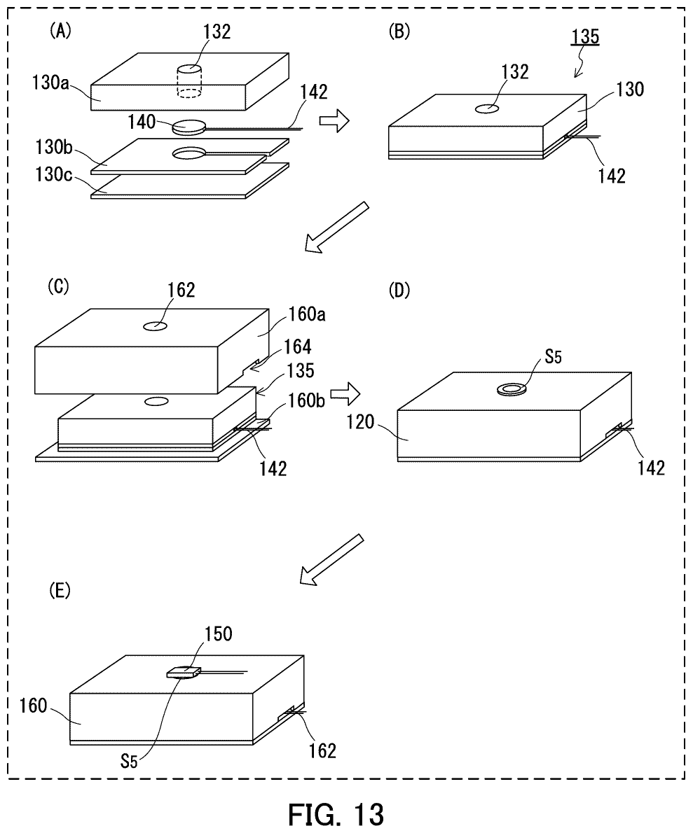

A method for measuring the insertion loss of the waterproof membrane for sound in the frequency range of 100 to 500 Hz will be described using FIG. 13. The insertion loss was measured by the following method using a simulated housing shown in FIG. 13 and modeled after a housing of a mobile phone.

As shown in (A) and (B) of FIG. 13, a speaker unit 135 to be enclosed in the simulated housing was produced. The detail is as follows. First, a speaker 140 (SCC-16A manufactured by STAR MICRONICS CO., LTD) as a sound source and fillers 130a, 130b, and 130c for enclosing the speaker 140 and preventing unnecessary diffusion of sound from the speaker (minimizing sound that enters a microphone for evaluation without passing through a waterproof membrane sample to be evaluated) were prepared, the fillers 130a, 130b, and 130c being formed of urethane sponge. The filler 130a is provided with a sound transmission port 132 having a 5 mm-diameter circular cross-section and extending in a thickness direction of the filler 130a. The filler 130b is provided with a cutout having a shape matching that of the speaker 140 and a cutout in which a speaker cable 142 is to be enclosed and that is for leading the speaker cable 142 to the outside of the speaker unit 135. Next, the fillers 130c and 130b were stacked, and the speaker 140 and the speaker cable 142 were enclosed in the cutouts of the filler 130b. Subsequently, the filler 130a was stacked thereon so that sound would be transmitted from the speaker 140 to the outside of the speaker unit 135 through the sound transmission port 132. The speaker unit 135 was thus obtained ((B) of FIG. 13).

Next, as shown in (C) of FIG. 13, the above speaker unit 135 was enclosed inside a simulated housing 160 (made of polystyrene and having outer dimensions of 60 mm×50 mm×28 mm) modeled after a housing of a mobile phone. The detail is as follows. The simulated housing 160 prepared consists of two portions 160a and 160b, which are able to be fitted to each other. The portion 160a is provided with a sound transmission port 162 (having a 1 mm-diameter circular cross-section) for transmitting sound emitted from the speaker unit 135 enclosed inside to the outside of the simulated housing 160 and a guide hole 164 for leading the speaker cable 142 to the outside of the simulated housing 160. By fitting the portions 160a and 160b together, a space having no openings other than the sound transmission port 162 and the guide hole 164 is created inside the simulated housing 160. The fabricated speaker unit 135 was disposed on the portion 160b, and the portions 160a and 160b were fitted together to enclose the speaker unit 135 inside the simulated housing 160. This was done in such a manner that the sound transmission port 132 of the speaker unit 135 and the sound transmission port 162 of the portion 160a were aligned to transmit sound from the speaker 140 to the outside of the simulated housing 160 through both of the sound transmission holes 132 and 162. The speaker cable 142 was drawn outside the simulated housing 160 through the guide hole 164, and the guide hole 164 was filled with putty.

Next, the waterproof membrane to be evaluated was cut into a circular shape having a diameter of 5.8 mm, which was employed as a sample S₅. A piece of double-sided pressure-sensitive adhesive tape A was adhered to each of the principal surfaces of the sample S₅. The pieces of the tape A was adhered to the sample S₅ such that the outer circumference of the pieces of the tape and the circumference of the sample S₅ were aligned. Then, the sample S₅ was fixed to the sound transmission port 162 of the simulated housing 160 using one of the pieces of the tape A. The sample S₅ was fixed such that the entire sound transmission region (a circular region of the one piece of double-sided pressure-sensitive adhesive tape A, the circular region having a diameter of 1.5 mm, the circular region corresponding to the opening portion) is located inside the opening of the sound transmission port 162 when viewed in a direction perpendicular to the principal surface of the membrane. Subsequently, a microphone 150 (SPU0410LR5H manufactured by Knowles Acoustics) was fixed so as to cover the sound transmission region of the sample S₅. The microphone 150 was fixed to the sample S₅ using the other piece of the tape A.

A distance between the speaker 140 and the fixed microphone 150 may vary by approximately 2 mm at most depending on the thickness of the sample S₅ to be evaluated, and was in the range of about 22 mm to about 24 mm. Subsequently, the speaker 140 and the microphone 150 were connected to an acoustic evaluation device (Multi-analyzer System 3560-B-030 manufactured by B&K Sound & Vibration Measurement A/S). A solid state response (SSR) mode (test signal: 20 Hz to 20 KHz; sweep up) was selected as evaluation mode, and an insertion loss of the sample S₅ for sound in the frequency range of 100 to 500 Hz was evaluated. The insertion loss was automatically determined on the basis of a test signal input to the speaker 140 from the acoustic evaluation system and a signal received by the microphone 150. The value (blank value) of an insertion loss in the absence of the sample S₅ had been determined in advance of the evaluation of the insertion loss of the sample S₅. The blank value was −24 dB at a frequency of 1 kHz. The insertion loss of the sample S₅ is a value determined by subtracting the blank value from the value measured by the acoustic evaluation system. A smaller insertion loss indicates better maintenance of the level (volume) of the sound output from the speaker 140.

The insertion loss of the sample S₅ for sound in the frequency range of 100 to 500 Hz was measured by the above-described method, and the measured value was considered the insertion loss of the waterproof membrane for sound in the frequency range of 100 to 500 Hz.

### [Relationship Between Elastic Modulus and Water Entry Pressure of Waterproof Membrane]

Silicone rubbers A, B, and D were prepared as raw materials. The silicone rubber A had a high hardness. The silicone rubber B had a low hardness. The silicone rubber D had a medium hardness. A shaping process was performed using each raw material to fabricate a membrane having a thickness of 30 μm. The membrane was non-porous. The membrane was cut to a strip having a width of 5 mm and a length of 60 mm, which was employed as a sample piece. The sample piece formed of the silicone rubber A was employed as Sample 1. The sample piece formed of the silicone rubber B was employed as Sample 2. The sample piece formed of the silicone rubber D was employed as Sample 3. Note that the silicone rubber D is identical to the silicone rubber (hardness: 65) used in Examples 1 and 2 in JP 2013-109932 (JP 2014-007738 A) of the present applicant.

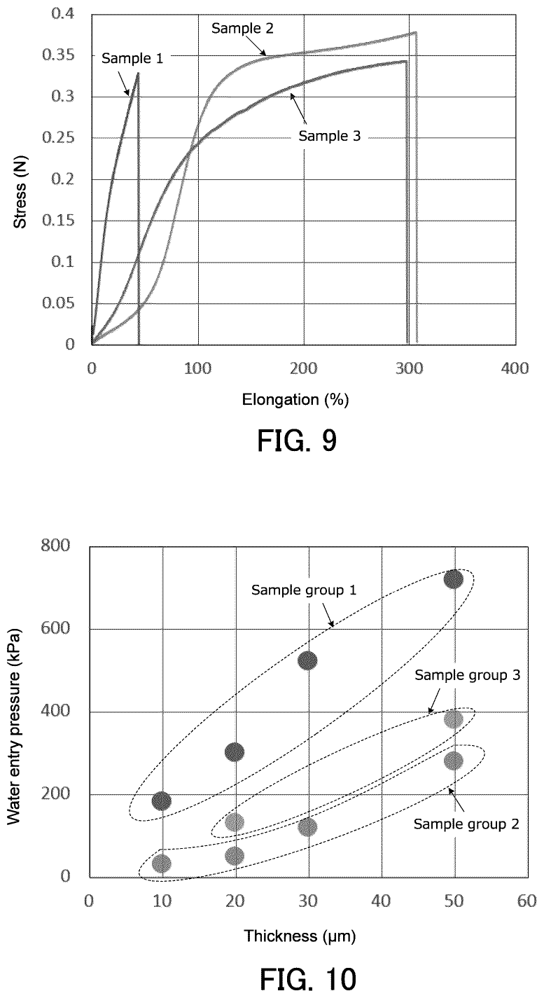

For Samples 1 to 3, a tensile test was performed by the same method as the above-described method for measuring the initial modulus Eₜ to measure the stress and the elongation. FIG. 9 shows elongation-stress relationships obtained by the tensile test for Samples 1 to 3.

As shown in FIG. 9, Sample 1 formed of the high hardness silicone rubber A exhibited the largest stress at an elongation of 10%. That is, the initial modulus Eₜ of Sample 1 is largest.

Next, a shaping process was performed using each of the above raw materials at varying thicknesses to fabricate a plurality of membranes having different thicknesses. All membranes were non-porous membranes. Each membrane produced was employed as a sample piece. A group of the sample pieces formed of the silicone rubber A was defined as Sample group 1. A group of the sample pieces formed of the silicone rubber B was defined as Sample group 2. A group of the sample pieces formed of the silicone rubber D was defined as Sample group 3.

For Sample groups 1 to 3, the water entry pressure was measured for each of the sample pieces having different thicknesses. FIG. 10 shows relationships between thickness and water entry pressure for Sample groups 1 to 3.

As can be understood from FIG. 9 and FIG. 10, the larger the initial modulus Eₜ is, the higher the water entry pressure tends to be. As can be seen in FIG. 10, the larger thickness the membrane has, the higher the water entry pressure tends to be.

### [Properties of Waterproof Membrane]

Next, the properties of waterproof membranes formed of the silicone rubbers were evaluated.

### Comparative Example 1

A shaping process in which the areal density was adjusted so that the membrane would have a thickness of 30 μm was performed using the silicone rubber A according to the above manufacturing method to fabricate a membrane. The membrane was non-porous. This membrane was employed as a membrane of Comparative Example 1. The initial modulus Eₜ, the water entry pressure, the insertion loss, the storage modulus E′, etc. were evaluated for Comparative Example 1. Table 1 shows the results.

### Comparative Example 2

A shaping process in which the areal density was adjusted so that the membrane would have a thickness of 30 μm was performed using the silicone rubber B according to the above manufacturing method to fabricate a membrane. The membrane was non-porous. This membrane was employed as a membrane of Comparative Example 2. The initial modulus Eₜ, the water entry pressure, the insertion loss, the storage modulus E′, etc. were evaluated for Comparative Example 2. Table 1 shows the results.

### Example 1

A shaping process in which the areal density was adjusted so that the membrane would have a thickness of 30 μm was performed using a mixture C1 according to the above manufacturing method to fabricate a membrane, the mixture C1 being obtained by mixing the silicone rubber A and the silicone rubber B in a mass ratio of 4:6. The membrane was non-porous. This membrane was employed as a membrane of Example 1. The initial modulus Eₜ, the water entry pressure, the insertion loss, the storage modulus E′, etc. were evaluated for Example 1. Table 1 shows the results.

### Example 2

A membrane was fabricated in the same manner as in Example 1, except that the areal density was adjusted in the shaping process so that the membrane would have a thickness of 15 μm. The membrane was non-porous. This membrane was employed as a membrane of Example 2. The initial modulus Eₜ, the water entry pressure, the insertion loss, the storage modulus E′, etc. were evaluated for Example 2. Table 1 shows the results.

### Example 3

A shaping process in which the areal density was adjusted so that the membrane would have a thickness of 30 μm was performed using a mixture C2 according to the above manufacturing method to fabricate a membrane, the mixture C2 being obtained by mixing the silicone rubber A and the silicone rubber B in a mass ratio of 6:4. The membrane was non-porous. This membrane was employed as a membrane of Example 3. The initial modulus Eₜ, the water entry pressure, the insertion loss, the storage modulus E′, etc. were evaluated for Example 3. Table 1 shows the results.

### Example 4

One of the principal surfaces of a membrane as produced in Example 1 was subjected to an oil-repellent treatment in which an oil repellent agent solution was applied to the one principal surface and dried by the above method. As the oil repellent agent was prepared a mixture of oil repellent agent a including a polymer including a compound represented by the following chemical formula (a) as a monomer and a solvent.

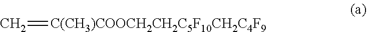

The solvent was added so that the concentration of the oil repellent agent a in the oil-repellent treatment solution would be 1.0 weight %. The solvent was a solution mixture of 1,1,2,2-tetrafluoroethoxy-1-(2,2,2-trifluoro) ethane (hereinafter referred to as HFE-347pc-f) (AE-3000 manufactured by AGC Inc.) and meta-xylene hexafluoride (hereinafter referred to as MX-HF). The mixing ratio of HFE-347pc-f to MX-HF was 3:1 in volume. The membrane obtained by the oil-repellent treatment was employed as a membrane of Example 4. The initial modulus Eₜ, the water entry pressure, the insertion loss, the storage modulus E′, etc. were evaluated for Example 4. Table 1 shows the results.

### Comparative Example 3

A shaping process in which the areal density was adjusted so that the membrane would have a thickness of 30 μm was performed using the silicone rubber D according to the above manufacturing method to fabricate a membrane. The membrane was non-porous. This membrane was employed as a membrane of Comparative Example 3. The initial modulus Eₜ, the water entry pressure, the insertion loss, the storage modulus E′, etc. were evaluated for Comparative Example 3. Table 1 shows the results.

TABLE 1

| | | | | | | | | Water | | |
|---|---|---|---|---|---|---|---|---|---|---|
| | | Oil- | | | Areal | Initial | Puncture | entry | | Storage |
| | Raw | repellent | Hardness | Thickness | density | modulus | modulus | pressure | Insertion | modulus |
| | material | treatment | H_{A} | (μm) | (g/m²) | Eₜ (MPa) | Eₚ (MPa) | (kPa) | loss (dB) | E′ (Pa) |
| Comp. | A | — | 79 | 30 | 69 | 160 | 51 | 520 | 16 | 1.2 × 10⁸ |
| Ex. 1 | | | | | | | | | | |
| Comp. | B | — | 22 | 30 | 48 | 2 | 0.6 | 70 | 0.5 | 2.3 × 10⁶ |
| Ex. 2 | | | | | | | | | | |
| Ex. 1 | C1 | — | 52 | 30 | 60 | 32 | 9.5 | 210 | 1.2 | 6.8 × 10⁶ |
| Ex. 2 | C1 | — | 52 | 15 | 31 | 32 | 9.5 | 170 | 0.9 | 6.8 × 10⁶ |
| Ex. 3 | C2 | — | 56 | 30 | 62 | 54 | 23 | 300 | 3.5 | 7.3 × 10⁶ |
| Ex. 4 | C1 | Performed | 52 | 30 | 61 | 33 | 12 | 215 | 1.3 | 6.9 × 10⁶ |
| Comp. | D | — | 65 | 30 | 50 | 28 | 8 | 160 | 3.8 | 7.8 × 10⁶ |
| Ex. 3 | | | | | | | | | | |

As shown in Table 1, for Examples 1 to 4 where the storage modulus E′ was 2.5×10⁶ Pa or more and 7.5×10⁶ Pa or less and the initial modulus Eₜ was 30 MPa or more and 100 MPa or less, the insertion loss for sound in the low frequency region (the frequency range of 100 to 500 Hz) was suppressed to 10 dB or less and the water entry pressure was 200 kPa or more, which demonstrates high waterproof properties. From these results, the membranes of Examples 1 to 4 are thought to be suitable for achieving both the waterproof properties and the sound transmission properties at the same time.

Additionally, as shown in Table 1, for Examples 1 to 4 where the storage modulus E′ was 2.5×10⁶ Pa or more and 7.5×10⁶ Pa or less and the puncture modulus Eₚ was 9.0 MPa or more and 40 MPa or less, the insertion loss for sound in the low frequency region (the frequency range of 100 to 500 Hz) was suppressed to 10 dB or less and the water entry pressure was 200 kPa or more, which demonstrates high waterproof properties. From these results as well, the membranes of Examples 1 to 4 are thought to be suitable for achieving both the waterproof properties and the sound transmission properties at the same time.

Each of the membranes of Examples 1 to 4 and Comparative Example 3 has medium hardness. However, the waterproof properties and sound transmission properties of Examples 1 to 4 are higher than those of Comparative Example 3.

The membrane of Example 1 has a larger areal density than that of the membrane of Example 2, and has enhanced waterproof properties. In spite of the increased areal density, an increase in insertion loss was suppressed in Example 1.

The membrane of Example 4 is a membrane fabricated by subjecting one of the surfaces of the membrane of Example 1 to the oil-repellent treatment, and has enhanced water entry pressure. Meanwhile, in Example 4, an increase in insertion loss was very limited. From these results, the effect of the oil-repellent treatment on the sound transmission properties of a waterproof membrane formed of an elastomer is thought to be small.

For Examples and Comparative Examples above, the properties of the waterproof membranes including the silicone rubbers as a raw material were evaluated. It should be noted that the effects comparable to those described above are expected even from a waterproof membrane including a raw material other than silicone rubber, such as urethane rubber or polytetrafluoroethylene, if the waterproof membrane has a storage modulus E′ of 2.5×10⁶ Pa or more and 7.5×10⁶ Pa or less and satisfies at least one selected from (i) and (ii) below:
(i) the initial modulus Eₜ measured by the tensile test is 30 MPa or more and 100 MPa or less; and
(ii) the puncture modulus Eₚ measured according to the puncture strength test specified in JIS Z 1707: 2019 is 9.0 MPa or more and 40 MPa or less, the puncture modulus Eₚ being calculated by dividing a maximum stress applied just before a needle penetrates the waterproof membrane 1 by the amount of displacement of the waterproof membrane 1 in the puncture direction at the maximum stress.

### INDUSTRIAL APPLICABILITY

The technique of the present invention can be applied to various electronic devices including: wearable devices such as smart watches; various cameras; communication devices such as mobile phones and smartphones; and sensor devices.

1. A waterproof member comprising a waterproof membrane, wherein the waterproof membrane has a storage modulus E′ of 2.5×10⁶ Pa or more and 7.5×10⁶ Pa or less as measured by a dynamic mechanical analysis test in tensile mode in a frequency range of 100 to 500 Hz and satisfies at least one selected from (i) and (ii) below:
(i) an initial modulus measured by a tensile test is 30 MPa or more and 100 MPa or less; and
(ii) a puncture modulus measured according to a puncture strength test specified in JIS Z 1707: 2019 is 9.0 MPa or more and 40 MPa or less, the puncture modulus being calculated by dividing a maximum stress applied just before a needle penetrates the waterproof membrane by an amount of displacement of the waterproof membrane in a puncture direction at the maximum stress.

2. The waterproof member according to claim 1, wherein an insertion loss of the waterproof membrane for sound in a frequency range of 100 to 500 Hz is 10 dB or less.

3. The waterproof member according to claim 1, wherein a water entry pressure measured for the waterproof membrane according to Method B (high water pressure method) of a water penetration test specified in JIS L 1092: 2009 is 200 kPa or more and 300 kPa or less.

4. The waterproof member according to claim 1, wherein a hardness measured for the waterproof membrane according to a type A durometer hardness test specified in JIS K 6253: 2012 is 40 or more and 60 or less.

5. The waterproof member according to claim 1, wherein the waterproof membrane includes an elastomer.

6. The waterproof member according to claim 5, wherein the elastomer includes at least one selected from the group consisting of silicone rubber and urethane rubber.

7. The waterproof member according to claim 5, wherein the elastomer is silicone rubber.

8. The waterproof member according to claim 7, wherein an areal density of the waterproof membrane is greater than 30 g/m².

9. The waterproof member according to claim 5, wherein the elastomer is a mixture of a high hardness elastomer and a low hardness elastomer.

10. The waterproof member according to claim 1, wherein at least one principal surface of the waterproof membrane is subjected to an oil-repellent treatment.

11. The waterproof member according to claim 1, wherein the waterproof membrane includes a colorant.

12. The waterproof member according to claim 1, further comprising a pressure-sensitive adhesive layer joined to the waterproof membrane.

13. A waterproof case comprising:
a case including a frame having an opening; and
the waterproof member according to claim 1 disposed on the frame to cover the opening.

14. An electronic device comprising:
a housing having an opening; and
the waterproof member according to claim 1 disposed on the housing to cover the opening.
